(19) United States
(12) Patent Application Publication
(10) Pub. No.: US 2026/0101639 A1
(43) Pub. Date: Apr. 9, 2026

(54) THIN ANODE HIGH RESOLUTION ADVANCED OLED SUB-PIXEL CIRCUIT AND PATTERNING

(71) Applicant: Applied Materials, Inc., Santa Clara, CA (US)

(72) Inventor: Jungmin LEE, Santa Clara, CA (US)

(21) Appl. No.: 18/955,190

(22) Filed: Nov. 21, 2024

Related U.S. Application Data
(60) Provisional application No. 63/704,895, filed on Oct. 8, 2024.

(51) Int. Cl. H10K 59/122; H10K 59/12

(52) U.S. Cl. CPC H10K 59/122; H10K 59/1201

(57) ABSTRACT

In one or more embodiments, a sub-pixel circuit includes at least two isolation structures disposed over a substrate, wherein adjacent isolation structures define a well. Anodes are disposed over an upper surface of the isolation structures. The sub-pixel circuit further includes overhang structures. The overhang structures have a layer including an upper portion having a bottom surface disposed on an outer portion of the anodes. The layer further includes a lower portion with a lowermost surface disposed on the isolation structures and extending past a sidewall of the isolation structures and over the well. The layer further includes an upper sidewall, adjacent upper sidewalls defining an opening of the well. The sub-pixel circuit further includes an organic light emitting diode (OLED) material, a cathode, and an encapsulation layer.

### CROSS-REFERENCE TO RELATED APPLICATIONS

This application claims priority to United States Provisional Patent Application Ser. No. 63/704,895, filed Oct. 8, 2024, the contents of which are incorporated herein by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution, i.e., pixel-per-inch, than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance.

Accordingly, what is needed in the art are sub-pixel circuits and methods of forming sub-pixel circuits to increase pixel-per-inch and provide improved OLED performance.

### SUMMARY

Embodiments described herein generally relate to a display. More specifically, embodiments described herein relate to sub-pixel circuits and methods of forming sub-pixel circuits that may be utilized in a display such as an organic light-emitting diode (OLED) display.

In one or more embodiments, a sub-pixel circuit includes at least two isolation structures disposed over a substrate, wherein adjacent isolation structures define a well. Anodes are disposed over an upper surface of the isolation structures. The sub-pixel circuit further includes overhang structures. The overhang structures have a layer including an upper portion having a bottom surface disposed on an outer portion of the anodes. The layer further includes a lower portion with a lowermost surface disposed on the isolation structures and extending past a sidewall of the isolation structures and over the well. The layer further includes an upper sidewall, adjacent upper sidewalls defining an opening of the well. The sub-pixel circuit further includes an organic light emitting diode (OLED) material, a cathode, and an encapsulation layer.

In one or more embodiments, a device includes a first sub-pixel and a second sub-pixel each including isolation structures including an isolation material. The isolation structures are disposed over a substrate. The isolation structures further include an outer portion and a lower sidewall. Anodes are disposed over the isolation structures. The anodes include an uppermost surface. A plurality of overhang structures include an overhang material. The overhang structures are disposed over the outer portion of the isolation substrate. The plurality of overhang structures further include an upper portion having a bottom surface disposed on an outer portion of the anodes and a lower portion with a lowermost surface disposed on of the isolation structures and extending past the sidewall of the isolation structures The portion of the bottom surface extending past the lower sidewall of the isolation structures defines an overhang extension. The lower sidewall of the isolation structure and a bottom surface of the overhang extension of the lower portion partially define a trench area. The device further includes an organic light emitting diode (OLED) material.

In one or more embodiments, a method includes depositing an isolation layer over a substrate, depositing an anode layer over the isolation layer, and forming a plurality of anodes using a photolithography process. The method further includes depositing an overhang layer over the isolation layer and the anodes, etching a portion of the overhang layer, and performing a reactive ion etching (RIE) process to form a plurality of isolation structures and a plurality of overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit at section line 1A-1A according to embodiments.

FIG. 1B is a schematic, cross-sectional view of a sub-pixel circuit at section line 1B-1B according to embodiments.

FIG. 1C is a schematic, cross-sectional view of a sub-pixel circuit having a line-type architecture according to embodiments.

FIG. 2 is a schematic, cross-sectional view of an overhang structure according to embodiments.

FIG. 3 is a flow diagram of a method for forming a sub-pixel according to according to embodiments.

FIGS. 4A-4R are schematic, cross-sectional views of a substrate during a method of forming a sub-pixel according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

In one embodiment, a sub-pixel is provided. The sub-pixel includes an isolation structure, an anode, overhang structures, separation structures, an organic light emitting diode (OLED) material, and a cathode. The isolation structure is formed on a substrate. In one or more embodiments, the substrate is a backplane. The anode is defined by a metal layer formed over the isolation structure. The overhang structures, in some embodiments, are disposed on the isolation structure and extend over a well in-between the isolation structures along a pixel plane. The overhang structures have an overhang extension that extends past a lower sidewall of the isolation structure. E.g., a bottom surface of the overhang structure extends laterally past the lower sidewall of the isolation structure. In embodiments with a protective layer, the isolation structure is disposed on the protective layer. The isolation structure has a lower sidewall. The overhang structure has an upper sidewall. The upper sidewall extends past the lower sidewall. The isolation structure and the overhang structure include different compositions.

In some embodiments, the different compositions of the isolation structure and the overhang structure results in different etch rates such that the overhang structure has an extension that extends past a lower sidewall of the isolation structure as described herein. The separation structures are disposed on the isolation structure in-between the anodes along a line plane. The separation structure includes an overhang portion. The overhang portion extends over at least a portion of the anodes. The separation structure is formed of a material having the same composition as the overhang structure. The isolation structure and the separation structure include different compositions. In some embodiments, the different compositions of the separation structure and the isolation structure results in different etch rates. The OLED material is disposed over the anode, the overhang structures, the upper sidewall of the overhang structures, within the trench area, and the separation structures. In embodiments with the protective layer, the OLED material is disposed over the protective layer within the well, and an upper portion of the protective layer disposed over the anode. The cathode disposed over the OLED material.

In another embodiment, a device is disclosed. The device includes a plurality of sub-pixel lines. Each sub-pixel line includes at least a first sub-pixel and a second sub-pixel. The first sub-pixel and the second sub-pixel each include an isolation structure, an anode, overhang structures, separation structures, an organic light emitting diode (OLED) material, and a cathode. The isolation structure is formed on a substrate. In one or more embodiments, the substrate is a backplane. The anode is defined by a metal layer formed over the isolation structure. The overhang structures, in some embodiments, are disposed on the isolation structure and extend over a well, along opposite sidewalls of the isolation structures along a pixel plane. The overhang structures have an overhang extension that extends past a lower sidewall of the isolation structure. E.g., a bottom surface of the overhang structure extends laterally past the lower sidewall of the isolation structure. In embodiments with the protective layer, the isolation structure is disposed on the protective layer. The isolation structure has a lower sidewall. The overhang structure has an upper sidewall. The upper sidewall extends past the lower sidewall. The isolation structure and the overhang include different compositions.

In some embodiments, the different compositions of the isolation structure and the overhang structure results is different etch rates such that the overhang structure has an extension that extends past a lower sidewall of the isolation structure as described herein. The separation structures are disposed on the isolation structure in-between the anodes along a line plane. The separation structure includes an extension portion. The lower portion extends over at least a portion of the anodes. The separation structure is formed of a material having the same composition as the overhang structure. The isolation structure and the separation structure include different compositions. In some embodiments, the different compositions of the separation structure and the isolation structure results in different etch rates. The OLED material is disposed over the anode, the overhang structures, the upper sidewall of the overhang structures, within the trench area, and the separation structures. In embodiments with the protective layer, the OLED material is disposed over the protective layer within the well, and an upper portion of the protective layer disposed over the anode. The cathode disposed over the OLED material.

Each of the embodiments described herein of the sub-pixel circuit include a plurality of sub-pixels with each of the sub-pixels are defined by adjacent overhang structures that are permanent to the sub-pixel circuit. While the Figures depict two sub-pixels or three sub-pixels with each sub-pixel defined by adjacent overhang structures, the sub-pixel circuit of the embodiments described herein include a plurality of sub-pixels, such as two or more subpixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit. The overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

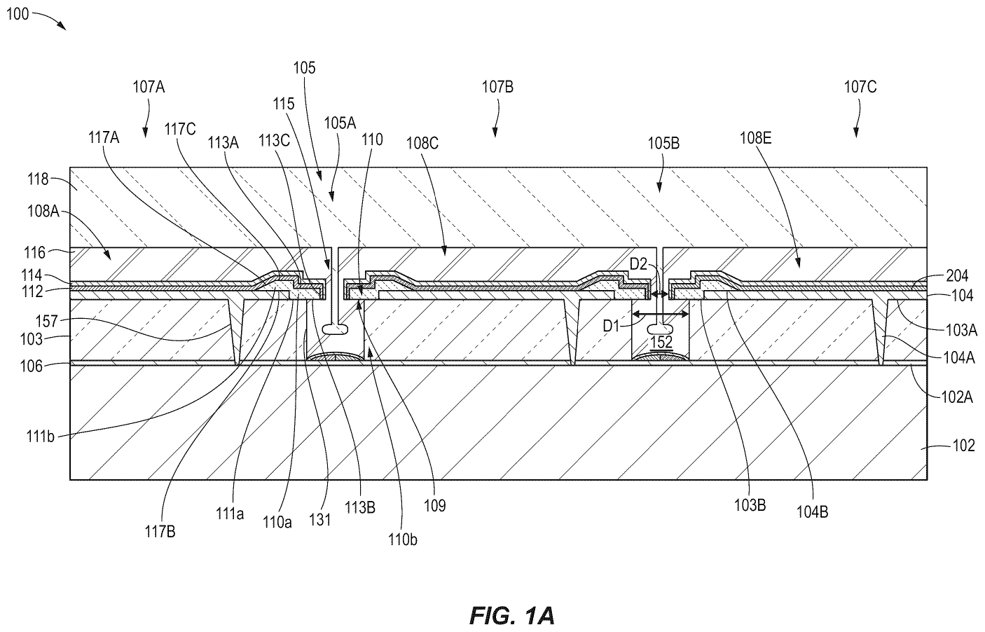

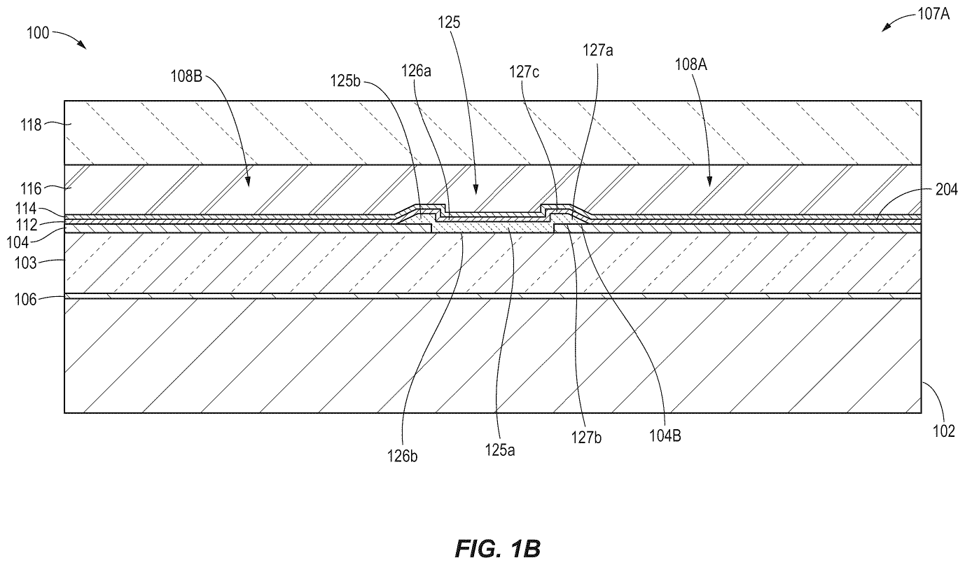

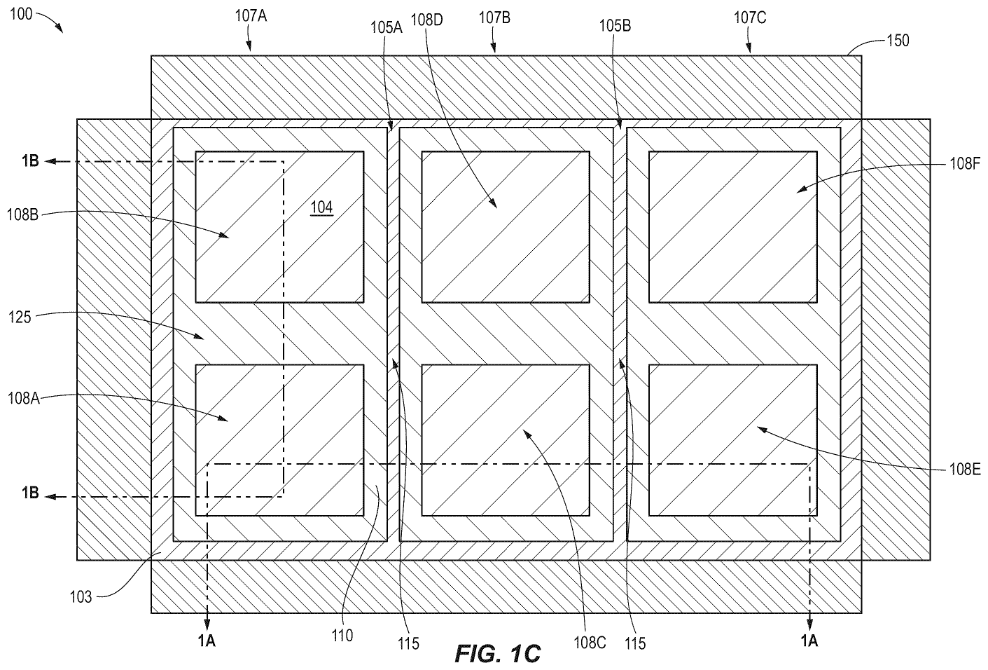

FIG. 1A is a schematic, cross-sectional view of a sub-pixel circuit 100, according to one or more embodiments. The cross-sectional view of FIG. 1A is taken along section line 1A-1A of FIG. 1C (e.g., a pixel plane). FIG. 1B is a schematic, cross-sectional view of a sub-pixel circuit 100 according to embodiments. The cross-sectional view of FIG. 1B is taken along section line 1B-1B of FIG. 1C (e.g., a line plane). The sub-pixel circuit 100 includes a substrate 102. In one or more embodiments, the substrate 102 is a backplane. The backplane includes, but is not limited to, a complementary metal-oxide-semiconductor (CMOS) array, a thin-film transistor (TFT) array, or a glass backplane.

A protective layer 106 may be disposed over the substrate 102. The protective layer 106 may be formed along both the pixel plane and the line plane. The protective layer 106 may be disposed on an upper surface of the substrate 102. The protective layer 106 is formed of a protective material. In one or more embodiments, the protective material includes aluminum oxide (Al₂O₃), Silicon Nitride (SiNₓ), Silicon Oxide (SiO₂), or a combination thereof. In one or more embodiments, the protective layer 106 has a thickness of about 10 nm to about 50 nm, such as a thickness of about 20 nm. In one or more embodiments, the protective layer has a thickness from about 100 nm to about 500 nm such as a thickness of about 300 nm.

Isolation structures 103 are formed on or over the substrate 102. In one or more embodiments, the isolation structures 103 are formed on or over the protective layer 106. The isolation structures 103 extend along line plane. Adjacent isolation structures 103 at least partially define a well 105. Each isolation structure includes an isolation material. In one or more embodiments, the isolation material includes aluminum oxide (Al₂O₃), Silicon Nitride (SiNₓ), Silicon Oxide (SiO₂), or a combination thereof. The isolation material and the protective material are different from one another. The isolation structures 103 have a thickness of about 0.5 μm to about 1 μm, such as a thickness of about 0.7 μm. In one or more embodiments, an opening 157 extends from an upper surface 103A of the isolation structure 103 to an upper surface 102A of the substrate 102.

Anodes 104 are patterned on or over the isolation structures 103. In one or more embodiments, the anodes 104 include indium tin oxide (ITO) anodes. In one or more embodiments the anodes 104 includes a transparent, conductive oxide (TCO) multilayer anode made of three layers. The three layers include a first layer of indium tin oxide (ITO), a second layer of silver (Ag), and a third layer of ITO. In one or more embodiments, the anode 104 has a thickness of about 10 nm to 50 nm, such as 20 nm. In one or more embodiments, the anode has a thickness of about 50 nm to about 150 nm, such as about 100 nm. The anodes 104 are configured to operate as anodes of respective sub-pixels. In one or more embodiments, a connecting portion 104A of each anode 104 extends through the opening 157 and contacts the substrate 102. In one or more embodiments, the connecting portion 104A of the anode 104 covers the outer surface of the opening 157. In one or more embodiments, a filling material is deposited within the opening 157 in order to fill the opening 157. In one or more embodiments the filling material includes copper. The connecting portion 104A of the anode 104 contacts one or more circuits formed on the substrate 102. In one or more embodiments, the connecting portion 104A of the anode 104 is a plug-in via metal. The plug in via metal includes a metal material, such as tungsten.

The sub-pixel circuit 100 has a plurality of sub-pixel lines (e.g., first sub-pixel line 107A, second sub-pixel line 107B, and third sub-pixel line 107C). The sub-pixel lines are adjacent to each other along the pixel plane. Each sub-pixel line includes at least two sub-pixels. E.g., the first sub-pixel line 107A includes a first sub-pixel 108A and a second sub-pixel 108B, the second sub-pixel line 107B includes a third sub-pixel 108C and a fourth sub-pixel 108D, and the third sub-pixel line 107C includes a fifth sub-pixel 108E and a sixth sub-pixel 108F. The first sub-pixel 108A and the second sub-pixel 108B are aligned along the line plane. The first sub-pixel 108A, the third sub-pixel 108C, and the fifth sub-pixel 108E are aligned in the pixel plane. While FIG. 1A depicts the first sub-pixel line 107A, the second sub-pixel line 107B, and the third sub-pixel line 107C, the sub-pixel circuit 100 of the embodiments described herein may additional sub-pixel lines such as a fourth sub-pixel line. Each sub-pixel line has OLED materials configured to emit a white, red, green, blue or other color light when energized. E.g., the OLED materials of the first sub-pixel line 107A emits a red light when energized, the OLED materials of the second sub-pixel line 107B emits a green light when energized, the OLED materials of the third sub-pixel line 107C emits a blue light when energized, and the OLED materials of a fourth sub-pixel emits another color light when energized. The OLED materials within a sub-pixel line may be configured to emit the same color light when energized. E.g., the OLED materials of the first sub-pixel 108A and the second sub-pixel 108B of the first sub-pixel line 107A emit a red light when energized and the OLED materials of the third sub-pixel 108C and the fourth sub-pixel 108D of the second sub-pixel line 107B emit a green light when energized.

Adjacent sub-pixel lines are divided by an opening 115 of a well 105 that extends along the line plane in-between the isolation structures 103 of adjacent sub-pixel lines. For example, FIG. 1A illustrates sub-pixel circuit 100 including a first well 105A and a second well 105B. The first well 105A is defined by the isolation structure 103 of the first sub-pixel 108A and the second sub-pixel 108B of first sub-pixel line 107A, and the isolation structure 103 of the third sub-pixel 108C and the fourth sub-pixel 108D of the second sub-pixel line 107B. The opening 115 of the first well 105A divides the first sub-pixel line 107A and the second sub-pixel line 107B. The second well 105B is defined by the isolation structure 103 of the third sub-pixel 108C and the fourth sub-pixel 108D of second sub-pixel line 107B, and the isolation structure 103 of the fifth sub-pixel 108E and the sixth sub-pixel 108F of the third sub-pixel line 107C. The opening 115 of the second well 105B divides the second sub-pixel line 107B and the third sub-pixel line 107C.

Each sub-pixel line includes a two overhang structures 110 extending along the line plane, disposed on an outer edge 103B of the isolation structures 103. The overhang structures include a lower portion 111a and an upper portion 111b. The lower portion 111a and the upper portion 111b are formed a continuous layer of the same material as one another. The lower portion 111a is disposed on or over the outer edge 103B of the isolation structure 103 and extends over at least a portion of the well 105. For example, the second sub-pixel line 107B includes a first overhang structure 110a and a second overhang structure 110b disposed on adjacent isolation structures 103 of the third sub-pixel 108C and the fourth sub-pixel 108D.

Each overhang structure 110 includes a lower portion 111a, and an upper portion 111b. The lower portion 111a is on or over the outer edge 103B of the isolation structure 103 and extends over at least a portion of the well 105. The lower portion 111a includes an upper surface 113A, a lowermost surface 113B, and an upper sidewall 113C. The lowermost surface 113B of the lower portion 111a extends past a lower sidewall 131 of the isolation structure 103. The upper portion 111b is disposed over an outer portion 104B of the anode 104. The upper portion 111b includes a tapered surface 117A, a bottom surface 117B, and a top surface 117C. In one or more embodiments, the bottom surface 117B of the upper portion 111b is coplanar to the upper surface 113A of the lower portion 111a. The overhang structure 110 includes an overhang material. The overhang material includes silicon (Si), silicon nitride (Si₃N₄), silicon oxide (SiO₂), aluminum oxide (Al₂O₃), or combinations thereof. The overhang material, the isolation material, and the protective material are all different from one another. The overhang material and the isolation material have different etch rates when exposed to etch chemistries. The lowermost surface 113B of the lower portion 111a extends past the lower sidewall 131 of the isolation structure 103 to form the overhang extension 109. The overhang extension 109 of the lower portion 111a allows for the overhang structure 110 to shadow a portion of the well 105. In one or more embodiments, the lowermost surface 113B of the lower portion 111a contacts the outer edge 103B of the isolation structure 103. The bottom surface 117B of the upper portion 111b extends over the outer portion 104B of the anodes 104. The lower sidewalls 131 and the overhang extensions 109 of the adjacent overhang structures 110 at least partially define a trench area 152 within the well 105. The lower sidewalls 131 of the adjacent isolation structures 103 are separated by a distance D1. The upper sidewalls 113C of the adjacent overhang structures 110 are separated by a distance D2.

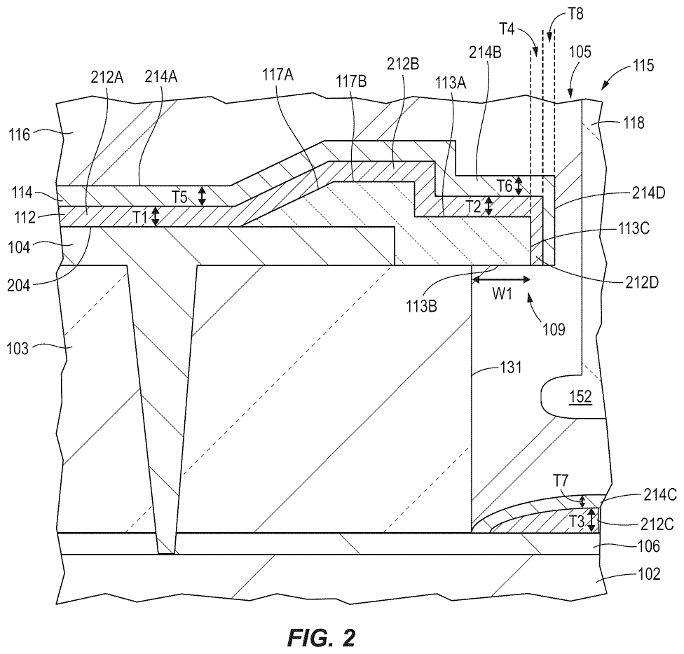

Each sub-pixel line includes an OLED material 112 and a cathode 114 disposed over the anode 104 and the overhang structures 110. The OLED material 112 may include one or more of a HIL, a HTL, an EML, and an ETL. The OLED material 112 is disposed over and in contact with the uppermost surface 204 of the anodes 104 within a sub-pixel line. In one or more embodiments, the OLED material 112 may be disposed the tapered surface 117A, the top surface 117C, and the upper surface 113A of the overhang structures 110. The OLED material 112 is disposed within at least a portion the trench area 152 not shadowed by the overhang extensions 109. Additionally, a thin layer of the OLED material 112 may be disposed over the upper sidewall 113C of the lower portion 111a. The thin layer of the OLED material 112 may also be disposed within a portion of the trench area 152 shadowed by the overhang extensions 109. The cathode 114 is disposed over the OLED material 112. The thickness of the OLED material 112 and the cathode 114 are described in greater detail in FIG. 2.

The cathode 114 includes a conductive material, such as a metal. E.g., the cathode 114 includes, but is not limited to, silver, magnesium, chromium, titanium, aluminum, ITO, or a combination thereof. In one or more embodiments, material of the cathode 114 is different from the overhang material. In one or more embodiments, an assistant cathode is deposited over the cathode 114. The assistant cathode may include a transparent conducting oxide (TCO) cathode. The TCO cathode may include one or more indium gallium zinc oxide (IGZO) layers, indium zinc oxide (IZO) layers, indium tin oxide (ITO) layers, or combinations thereof. In one more embodiments, the TCO cathode has a thickness from about 50 nm to about 100 nm.

The sub-pixel circuit 100 includes an encapsulation layer 116. The encapsulation layer 116 may be or may correspond to a local passivation layer. The encapsulation layer 116 of a respective sub-pixel is disposed over the cathode 114 (and OLED material 112) within the trench area 152, with the encapsulation layer 116 extending under at least a portion of each of the overhang extensions 109 and along the lower sidewall 131 of each of the adjacent isolation structures 103. The encapsulation layer 116 is disposed over the cathode 114 and over at least the lower sidewall 131. In some embodiments, which can be combined with other embodiments described herein, the encapsulation layer 116 is disposed over the upper sidewall 113C. In some embodiments, which can be combined with other embodiments described herein, the encapsulation layer 116 is disposed over upper surface 113A of the overhang structures 110. The encapsulation layer 116 includes the non-conductive inorganic material, such as the silicon-containing material. The silicon-containing material may include Si₃N₄ containing materials.

In one or more embodiments, as shown in FIGS. 1A and 1B, the encapsulation layer 116 extends over the cathode 114 disposed over the anode 104, and the overhang structures 110. The encapsulation layer 116 extends into the trench area 152 and contacts the lowermost surface 113B of the overhang extension 109, as well as the lower sidewall 131. Additionally, the encapsulation layer is disposed over the OLED material 112 and the cathode 114 within the trench area 152. The encapsulation layer 116 includes the non-conductive inorganic material, such as the silicon-containing material. The silicon-containing material may include Si₃N₄ containing materials. In one or more embodiments, a global encapsulation layer 118 is over the encapsulation layer 116. The global encapsulation layer 118 layer fills the trench area 152 and the opening 115 and covers the entirety of the sub-pixel circuit 100.

Each sub-pixel line includes one or more separation structures 125, with adjacent sub-pixels sharing a separation structure 125 in the line plane. The separation structures 125 are permanent to the sub-pixel circuit 100. The separation structures 125 further define each sub-pixel of the sub-pixel line. The separation structures 125 are disposed over the isolation structures 103 in-between the anodes 104 of the sub-pixels within a sub-pixel line. For example, FIG. 1B shows the first sub-pixel 108A and the second sub-pixel 108B of the first sub-pixel line 107A. The separation structure 125 is disposed between the anodes 104 of the first sub-pixel 108A and the second sub-pixel 108B. The separation structure 125 includes a separation portion 125a and an extension portion 125b. The separation portion 125a includes an upper surface 126a and a lower surface 126b. The separation portion 125a is disposed between the anode 104 of the first sub-pixel 108A and the anode 104 of the second sub-pixel 108B. The extension portion 125b includes a tapered surface 127a, a bottom surface 127b, and a top surface 127c. In one or more embodiments the bottom surface 127b of the extension portion 125b extends over an outer portion 104B of the anode 104. The separation structure 125 includes a separation material. The separation material includes silicon (Si), silicon nitride (Si₃N₄), silicon oxide (SiO₂), or combinations thereof. The separation material is the same as the overhang material.

The OLED material 112 is disposed over and in contact with the uppermost surface 204 of the anode 104 and the separation structure 125 in the line plane. The cathode 114 is disposed over the OLED material 112 in the line plane. The thickness of the OLED material 112 and the cathode 114 is substantially uniform in the line plane. The encapsulation layer 116 is disposed over the cathode 114 in the line plane. As shown in FIG. 1B, the OLED material 112, the cathode 114, and the encapsulation layer 116 maintain continuity along the length of the line plane in order to apply current across each sub-pixel line. In one or more embodiments, the global encapsulation layer 118 is disposed over the encapsulation layer 116 in the line plane.

FIG. 1C is a schematic, top view of a sub-pixel circuit 100, according to embodiments. It should be understood that FIG. 1C does not include the protective layer 106, OLED material 112, the cathode 114, the encapsulation layer 116, or the global encapsulation layer 118 for illustrative purposes. One or more busbars 150 are disposed adjacent to the substrate 102. The busbars 150 provide a current to the sub-pixel circuit 100. Although FIG. 1C depicts sub-pixel circuit 100 including four busbars 150, it is contemplated that any number of busbars can be used, including but not limited to one busbar, two busbars, three busbars, or six busbars.

FIG. 2 is a close up schematic, cross-sectional view of sub-pixel circuit 100, according to one or more embodiments. A first width W1 of the lowermost surface 113B of the overhang extension 109 is defined by a distance from the lower sidewall 131 of the isolation structure 103 to the upper sidewall 113C of the overhang structure 110. The OLED material 112 is disposed over the anode 104, the overhang structure 110, and inside the trench area 152. The OLED material 112 has four different portions. The first portion 212A of the OLED material 112 is disposed over the uppermost surface 204 of the anode 104. The first portion 212A is in direct contact with the anode 104. The first portion 212A has a first thickness T1. The first thickness T1 is the same across the entire first portion 212A. The second portion 212B of the OLED material 112 is disposed over tapered surface 117A, the top surface 117C, and the upper surface 113A of the overhang structure 110. The second portion 212B has a second thickness T2. The second thickness T2 is the same across the entire second portion 212B. The first thickness T1 and the second thickness T2 are substantially the same. A third portion 212C of the OLED material 112 is disposed over the substrate 102 or the protective layer 106 within the trench area 152. The third portion 212C within the well 105 has a varying third thickness T3. The third portion 212C is thickest directly under the opening 115 of the trench area 152. The third thickness T3 under the overhang extension 109 is less than the third thickness T3 under the opening 115 of the trench area 152. The third thickness T3 decreases as the third portion 212C approaches the lower sidewalls 131 of the isolation structure 103. The third thickness T3 under the opening 115 of the trench area 152 is substantially the same as the first thickness T1 and second thickness T2. The third thickness T3 under the overhang extension 109 is less than first thickness T1 and the second thickness T2. In some embodiments, as shown in FIG. 2, the third portion 212C contacts the sidewall of the lower portion 111a of the overhang structure 110. In other embodiments, not shown, the third portion 212C may not extend to the sidewall of the lower portion 111a of the overhang structure 110. The fourth portion 212D of the OLED material 112 is disposed over the upper sidewall 113C of the overhang structure 110. The fourth portion 212D has a fourth thickness T4. The fourth thickness T4 is less than the first thickness T1 and the second thickness T2. In some embodiments, a thin layer of OLED material 112 is disposed over the lower sidewall 131 of the isolation structure 103. In some embodiments, a thin layer of OLED material 112 is disposed over the lowermost surface 113B of the overhang extension 109.

The cathode 114 is disposed over the OLED material 112. The cathode 114 has four different portions. The first portion 214A of the cathode 114 is disposed over the first portion 212A of the OLED material 112. The first portion 214A has a fifth thickness T5. The fifth thickness T5 is the same across the entire first portion 212A. The second portion 214B of the cathode 114 is disposed over second portion 212B of the OLED material 112. The second portion 212B has a sixth thickness T6. The sixth thickness T6 is the same across the entire second portion 212B. The fifth thickness T5 and the sixth thickness T6 are substantially the same. A third portion 214C of the cathode 114 is disposed over the third portion 212C of the OLED material 112 within the trench area 152. The third portion 214C within the well 105 has a seventh thickness T7. The seventh thickness T7 under the opening 115 of the trench area 152 is substantially the same as the fifth thickness T5 and sixth thickness T6. The seventh thickness T7 under the overhang extension 109 is less than fifth thickness T5 and the sixth thickness T6. In some embodiments, as shown in FIG. 2, the third portion 214C contacts the sidewall 131 of the isolation structure 103. In other embodiments, not shown, the third portion 214C may not extend to the lower sidewall 131 of the isolation structure. The fourth portion 214D of the cathode 114 is disposed over the fourth portion 212D of the OLED material 112. The fourth portion 214D has an eighth thickness T8. The eighth thickness T8 is less than the fifth thickness T5 and the sixth thickness T6. In some embodiments, a thin layer of cathode 114 is disposed over the lower sidewall 131 of the isolation structure 103. In some embodiments, a thin layer of the cathode 114 is disposed over the lowermost surface 113B of the overhang extension 109.

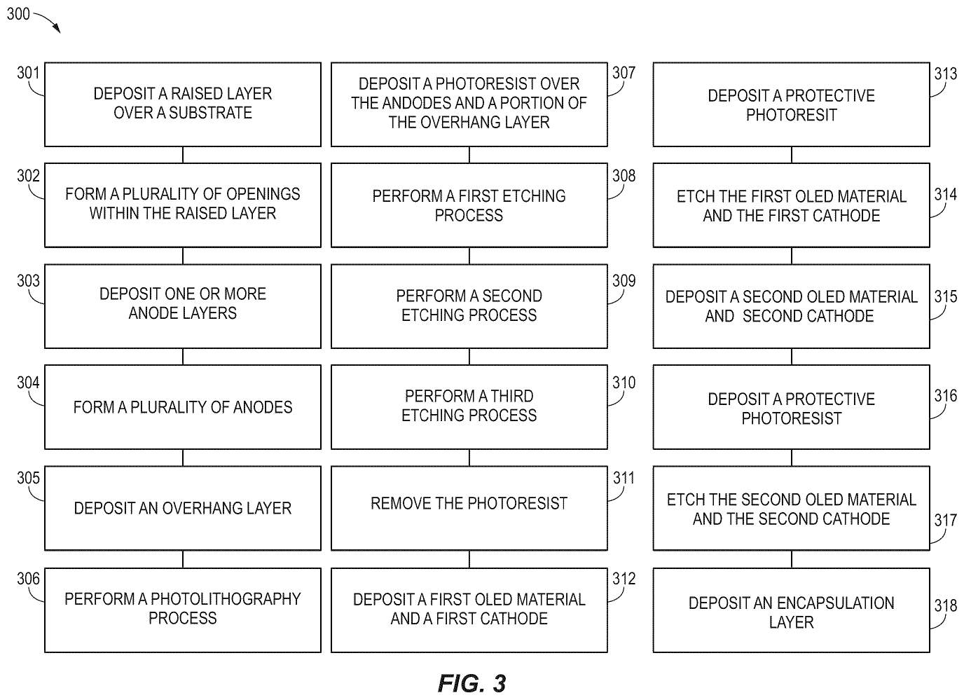

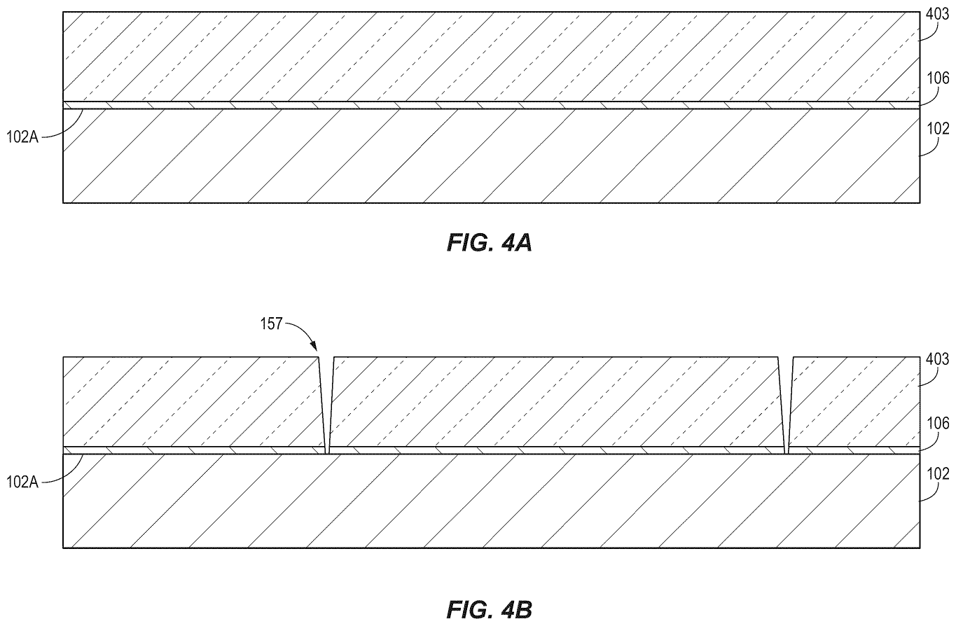

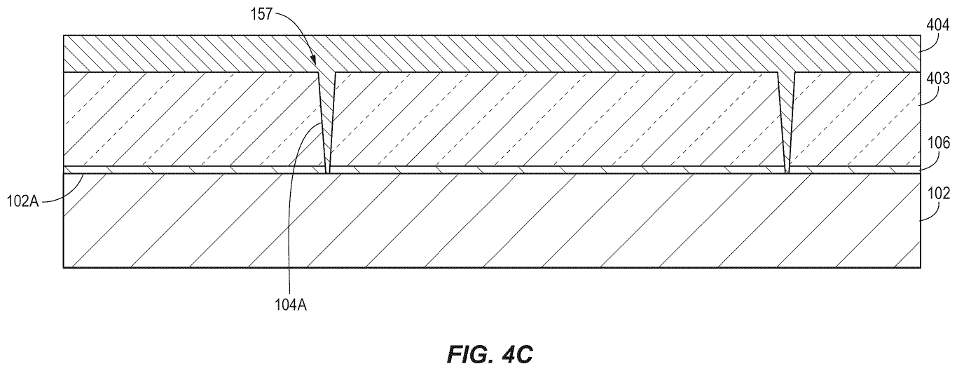

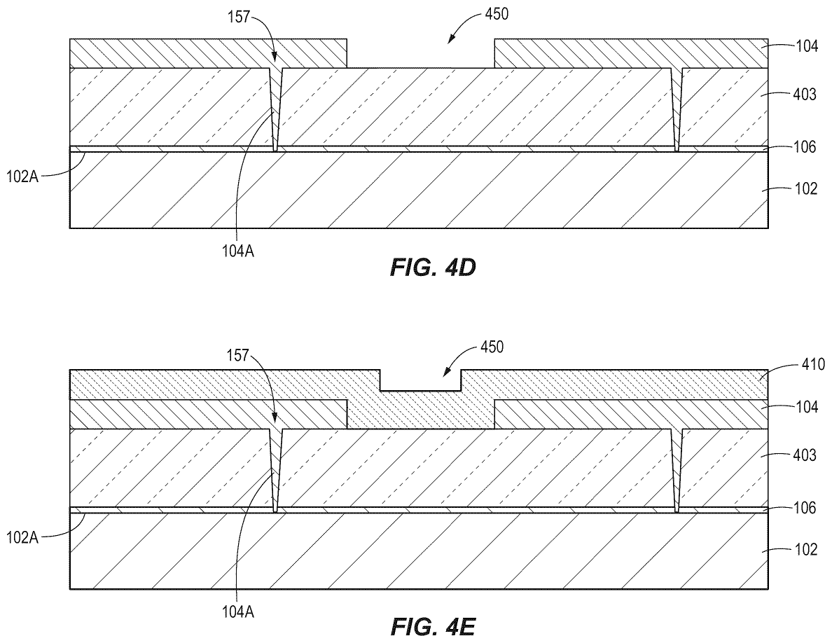

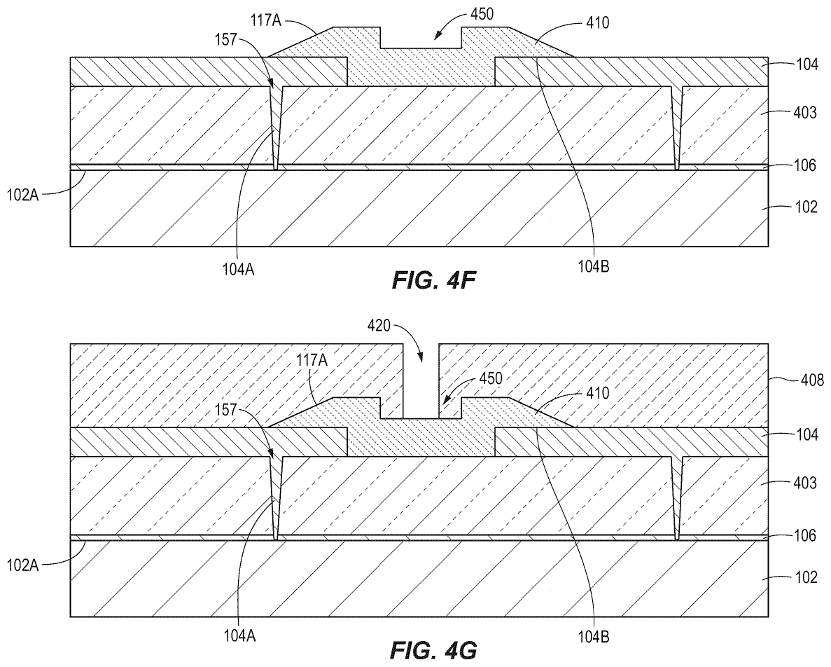

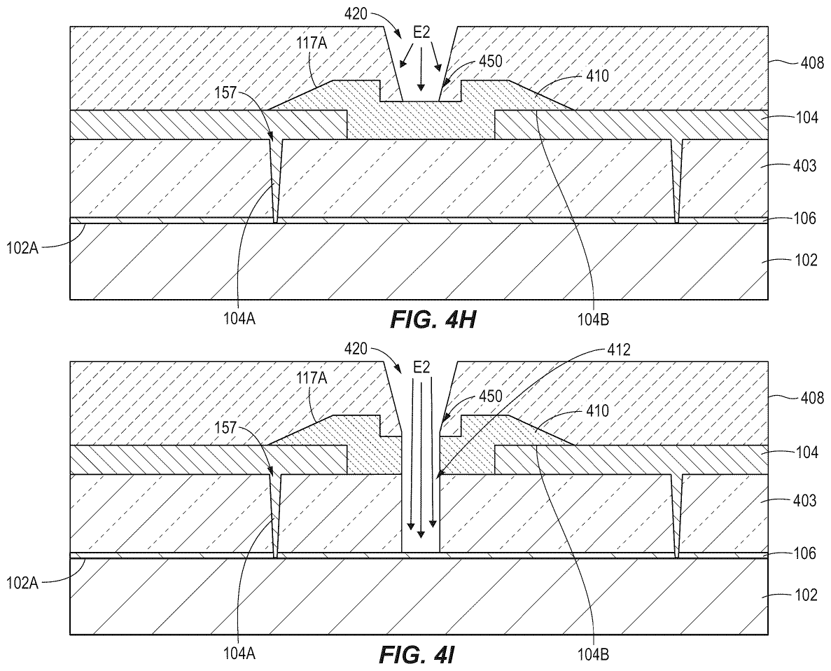

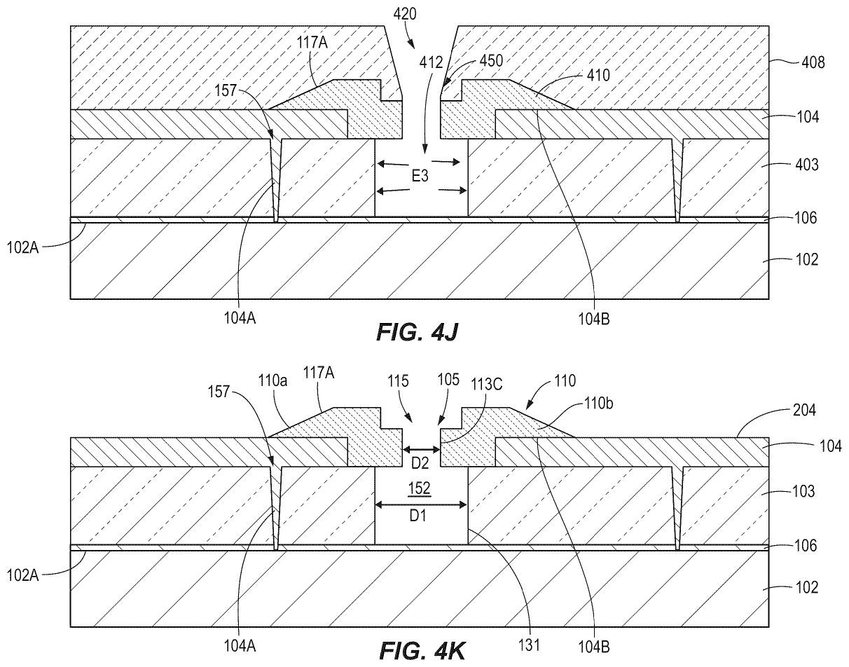

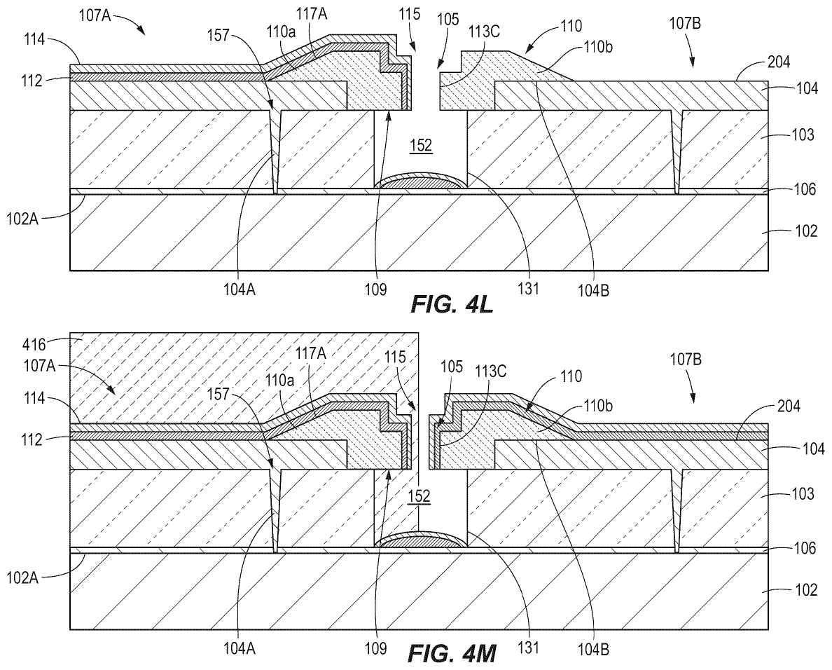

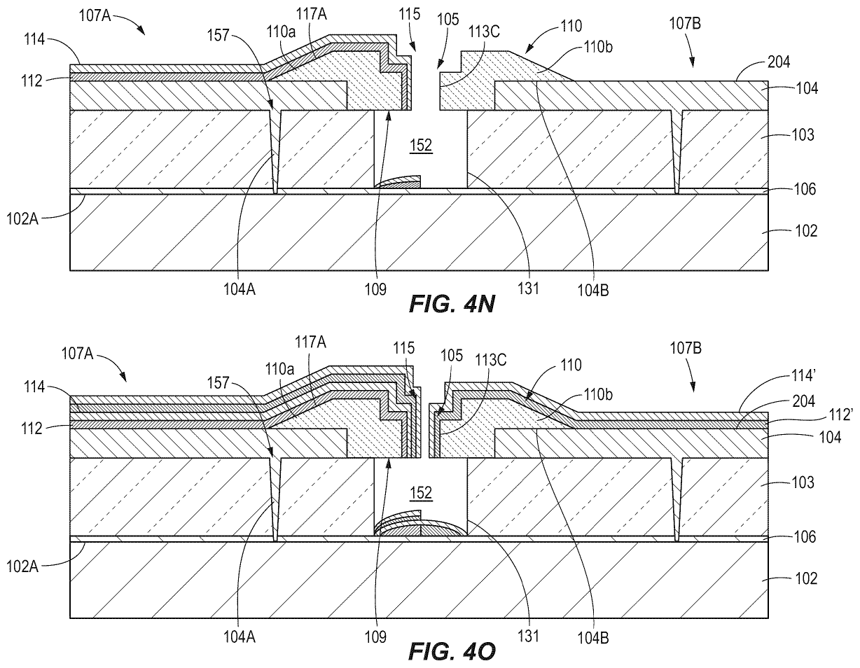

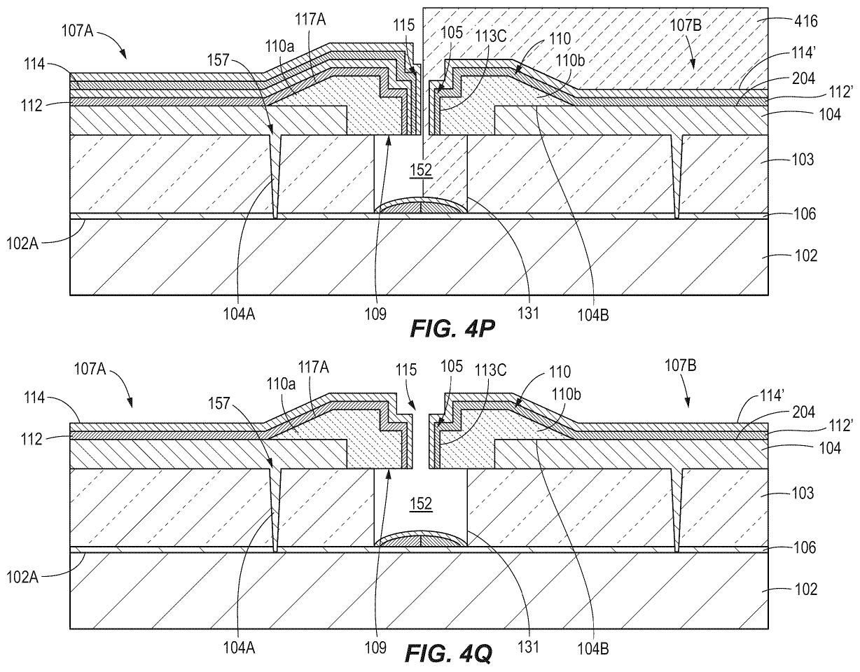

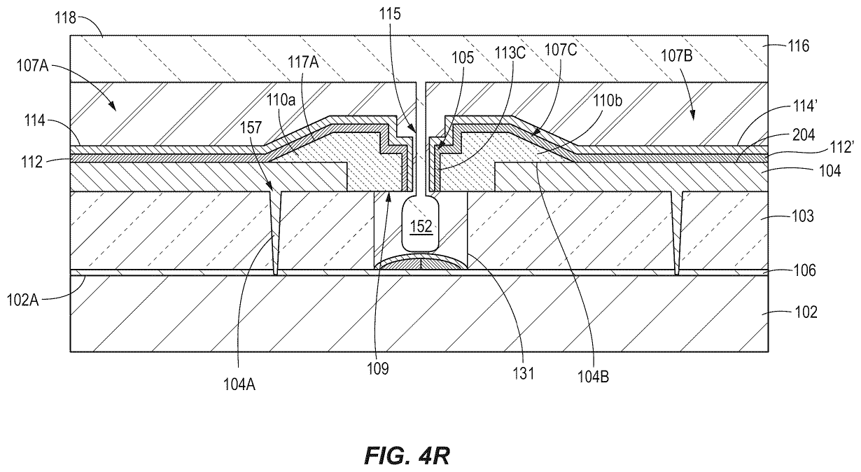

FIG. 3 is a flow diagram of a method 300 for forming a sub-pixel circuit 100 according to embodiment. FIGS. 4A-4Q are schematic, cross-sectional views of a substrate 102 during a method 300 for forming a sub-pixel circuit 100 according to embodiments described herein. It should be understood that although FIGS. 4A-4Q depict a substrate with two anodes, method 300 can be performed on a substrate with any number of anodes.

At operation 301, as shown in FIG. 4A (along the pixel plane), the protective layer 106 and an isolation layer 403 are deposited over a substrate 102. In one or more embodiments, the protective layer 106 is deposited on the upper surface 102A of the substrate 102. The protective layer 106 is formed of the protective material. The isolation layer 403 is deposited over the protective layer 106. The isolation layer is formed of the isolation material. The isolation material and the protective material are different from one another. The isolation layer 403 has a thickness of about 0.5 μm to about 1 μm, such as a thickness of about 0.7 μm. In one or more embodiment, the isolation layer 403 is not planarized.

At operation 302, as shown in FIG. 4B (along the pixel plane), a plurality of openings 157 are formed in the protective layer 106 and the isolation layer 403 using a photolithography process. During the photolithography process a photoresist is deposited and patterned over a desired portion of the isolation layer 403. After the photoresist is patterned, a portion of the isolation layer 403 and the protective layer 106 is removed by an etching process. The etching process can include both dry etching processes and wet etching processes. After the etching process the photoresist is removed. After operation 302 is performed the openings 157 extend from an upper surface of the isolation layer to the upper surface 102A of the substrate 102.

At operation 303, as shown in FIG. 4C (along the pixel plane), one or more anode layers 404 are deposited over the isolation layer 403. The one or more anode layers include one or more anode materials. The one or more anode materials include indium tin oxide (ITO), silver (Ag), or a combination thereof. In one or more embodiment, the one or more anode layers 404 are not planarized. A connecting portion 104A of the one or more anode layers 404 is deposited within the openings 157. The connecting portion 104A coats a surface of the openings 157. The connecting portion 104A extends through the opening 115 and contacts the upper surface 102A of the substrate 102. In one or more embodiments, the openings 157 are filled with one or more filling materials. The one or more filling materials include a polymide (PI) material, copper (Cu), or a combination thereof. In one or more embodiments, a plug in via metal is disposed within the openings 157 prior to the deposition of the one or more anode layers 404. After the plug-in via metal is deposited a chemical mechanical planarization (CMP) process is performed to planarize the plug-in via metal.

At operation 304, as shown in FIG. 4D (along the pixel plane), a plurality of anodes 104 are formed using a photolithography process. During the photolithography process a photoresist is deposited and patterned over a desired portion of the anode layer 404. After the photoresist is patterned, a portion of the anode layer 404 is removed by an etching process. The etching process can include both dry etching processes and wet etching processes. After the etching process the photoresist is removed. After operation 304 is performed a plurality of anodes 104 extending along the line plane are formed over the isolation layer 403. A gap 450 separates the anodes 104 along the pixel plane.

At operation 305, as shown in FIG. 4E (along the pixel plane), an overhang layer 410 is deposited over anodes 104 and the isolation layer 403. The overhang layer 410 is disposed on an uppermost surface of the anodes 104. The overhang layer 410 is further disposed on the upper surface of the isolation layer 403 within the gap 450. The overhang layer 410 includes the overhang material of the overhang structure 110. The difference in the isolation material and the overhang material results in different etch rates such that the overhang structure 110 has the overhang extension 109 that extends past a lower sidewall 131 of the isolation structure 103 as described herein. In one or more embodiment, the isolation layer 403 is not planarized.

At operation 306, as shown in FIG. 4F (along the pixel plane), the overhang layer 410 is etched using a photolithography process. During the photolithography process a photoresist is deposited and patterned over a desired portion of the overhang layer 410. After the photoresist is patterned, a portion of the overhang layer 410 disposed over the anodes 104 is removed by an etching process. The etching process can include both dry etching processes and wet etching processes. After the etching process the photoresist is removed. After the etching process is performed a portion of the overhang layer 410 disposed over the anodes 104 is removed. The remaining portion of the overhang layer 410 is disposed within the gap 450 and extends over an outer portion 104B of the anodes 104. In one or more embodiments, a second etching process is performed to form a tapered surface 117A on portion of the overhang layer 410 disposed over the outer portion 104B of the anodes 104.

At operation 307, as shown in FIG. 4G (along the line plane), a photoresist 408 is disposed over the anodes 104 and a portion of the overhang layer 410. An opening 420 is formed in the photoresist 408 over a center portion of the overhang layer 410 disposed within the gap 450. The opening 420 exposes a middle portion of the overhang layer 410. The opening 420 is in a range of about 100 nm to about 500 nm, such was in a range of about 200 nm to about 300 nm.

At operation 308, as shown in FIG. 4H (along the pixel plane) a first etching process E1 is performed. The first etching process E1 is the first step in a three step reactive ion etching (RIE) process. During the first etching process E1 an aluminum oxide (Al₂O₃) chlorine (Cl) based dry etch is used to widen opening 420 formed in the photoresist 408. The first etching process E1 is an anisotropic process. The overhang layer 410 may be slightly etched into as well.

At operation 309, as shown in FIG. 4I (along the pixel plane) a second etching process E2 is performed. The second etching process E2 is the second step in a three step reactive ion etching (RIE) process. During the second etching process E2 an etchant is used vertically etch a channel 412 through the overhang layer 410 and into the isolation layer 403. The etchant includes etchants such as a silicon monoxide (SiO) fluorine (F) based dry etch. The second etching process E2 is an anisotropic process. The second etching process E2 vertically etches into the channel 412 isolation layer 403. The etching process E2 is stopped before channel 412 reaches the protective layer 106. The channel 412 has a width within a range of about 200 nm to about 500 nm such as a width within a range of about 250 nm to about 400 nm.

At operation 310, as shown in FIG. 4J (along the pixel plane) a third etching process E3 is performed. The third etching process E3 is the third step in a three step reactive ion etching (RIE) process. During the third etching process E3 an etchant is used selectively etch the isolation layer 403. The isolation layer 403 is formed of the isolation material with the first etch rate. The overhang layer 410 is formed of the overhang material having the second etch rate. The different etch rates of the isolation material and the overhang material causes the isolation layer 403 to be widened greater rate than the overhang layer 410 during the third etching process. The channel 412 in the isolation layer 403 is widened during the third etching process E3. The etchant includes etchants such as silver (Ag) potassium (Kl) based wet etchant, or silver (Ag) iodine (I₂) based wet etchant.

The third etching process E3 is an isentropic process. The third etching process selectively etched the isolation layer 403, while avoiding etching into the overhang layer 410 and the protective layer 106. The third etching process E3 forms adjacent the overhang structures 110a, 110b and the well 105. The adjacent overhang structures 110a, 110b partially define the trench area 152. The third etching process E3 further forms the isolation structures 103. After the third etching process E3 is performed the lower sidewalls 131 of the isolation structures 103 are separated by a distance D1. After the third etching process E3 is performed the upper sidewalls 113C of the adjacent overhang structures 110a, 110b are separated by a distance D2. In one or more embodiments, the distance D2 is from about 400 nm to about 800 nm.

At operation 311, as shown in FIG. 4K (along the pixel plane) the photoresist 408 is removed. After operation 310 is performed, a portion middle of the uppermost surface 204 of the anodes 104 is exposed, while an outer portion 104B of the anodes 104 remains covered by the overhang structures 110.

At operation 312, as shown in FIG. 4L (along pixel plane), the first OLED material 112 of the first sub-pixel line 107A and the first cathode 114 are deposited. The first OLED material 112 includes an HIL material. The shadowing of the adjacent overhang extensions 109 within the trench area 152 provides for an electrical break in the OLED material 112 and the cathode 114. The first OLED material 112 and the first cathode 114 may separate (e.g., may be non-continuous) along the pixel plane. The first OLED material 112 and first cathode 114 maintain continuity along the line plane, e.g., the first OLED material 112 and the first cathode 114 are disposed over the separations structures 125. The total thickness of the first OLED material 112 and the first cathode 114 is from about 100 nm to about 150 nm.

At operation 313, as shown in FIG. 4M (along the pixel plane), a protective photoresist 416 is deposited over the first sub-pixel line 107A. The protective photoresist 416 extends over the anode 104 and the first overhang structure 110a within the first sub-pixel line 107A. The protective photoresist 416 extends into the opening 115 of the trench area 152. The protective photoresist covers the first OLED material 112 and the first cathode 114 disposed over the first overhang structure 110a and protects a portion of the first OLED material 112 and the first cathode 114 within the well 105. The protective photoresist does not cover the first OLED material 112 and the first cathode 114 disposed over the second overhang structure 110b.

At operation 314, as shown in FIG. 4N (along the pixel plane), the first OLED material 112 and the first cathode 114 disposed over the second sub-pixel line 107B is etched away. The first OLED material 112 and the first cathode 114 protected by the protective photoresist 416 is protected during the etching process. After the etching process is completed, the protective photoresist 416 is removed and the first OLED material 112 and the first cathode 114 that was covered by the protective photoresist 416 during the etching process remains.

At operation 315, as shown in FIG. 4O (along pixel plane), a second OLED material 112′ of the second sub-pixel line 107B and a second cathode 114′ of the second sub-pixel line 107B are deposited. The second OLED material 112′ includes an HIL material. The shadowing of the adjacent overhang extensions 109 provides within the trench area 152 provides for an electrical break in the second OLED material 112′ and the second cathode 114′. The second OLED material 112′ and the second cathode 114′ may separate (e.g., may be non-continuous) along the pixel plane. The second OLED material 112′ and second cathode 114′ maintain continuity along the line plane, e.g., the second OLED material 112′ and the second cathode 114′ are disposed over the separations structures 125. The total thickness of the second OLED material 112′ and the second cathode 114′ is from about 100 nm to about 150 nm.

At operation 316, as shown in FIG. 4P (along the pixel plane), a protective photoresist 416 is deposited over the second sub-pixel line 107B. The protective photoresist 416 extends over the anode 104 and the second overhang structure 110b within the second sub-pixel line 107B. The protective photoresist 416 extends into the opening 115 of the trench area 152. The protective photoresist covers the second OLED material 112′ and the second cathode 114′ disposed over the second overhang structure 110b and protects a portion of the second OLED material 112′ and the second cathode 114′ within the trench area 152. The protective photoresist does not cover the second OLED material 112′ and the second cathode 114′ disposed over the first overhang structure 110a and the first sub-pixel line 107A.

At operation 317, as shown in FIG. 4Q (along the pixel plane), the second OLED material 112′ and the second cathode 114′ of the second sub-pixel line 107B, disposed over the first sub-pixel line 107A is etched away. The second OLED material 112′ and the second cathode 114′ disposed over the first sub-pixel line 107A is etched away so that the cathode 114 of the first sub-pixel line 107A is exposed. The second OLED material 112′ and the second cathode 114′ of the second sub-pixel line 107B protected by the protective photoresist 416 is protected during the etching process. After the etching process is completed, the protective photoresist 416 is removed and the second OLED material 112′ and the second cathode 114′ that was covered by the protective photoresist during 416 the etching process remains. After the protective photoresist 416 is removed, the first sub-pixel line 107A includes the first OLED material 112 and the first cathode 114 of the first sub-pixel line 107A, and the second sub-pixel line 107B includes the second OLED material 112′ and the second cathode 114′ of the second sub-pixel line 107B.

At operation 318, as shown in FIG. 4R (along the pixel plane), an encapsulation layer 116 is deposited over the sub-pixel lines 107A, 107B. The encapsulation layer 116 extends over the cathodes 114, 114′ disposed over the anode 104, and the overhang structures 110. The encapsulation layer extends into the wells 105 and contacts a bottom surface of the overhang extension 109, as well as the lower sidewalls 131 of the isolation structures 103. Additionally, the encapsulation layer is disposed over the OLED materials 112, 112′ and the cathodes 114, 114′ within the trench area 152. The encapsulation layer 116 includes the non-conductive inorganic material, such as the silicon-containing material. The silicon-containing material may include Si₃N₄ containing materials. In one or more embodiments, a global encapsulation layer 118 may optionally be disposed over the encapsulation layer 116. The global encapsulation layer 118 layer fills the openings 115 of the trench area 152 and covers the entirety of the sub-pixel circuit 100.

Benefits of the present disclosure include increased pixels-per-inch, decreased current leakage, increased device performance, increased device image resolution, decreased cost, and decreased maintenance.

It is contemplated that one or more aspects disclosed herein may be combined. As an example, one or more aspects, features, components, operations and/or properties of the sub-pixel circuit 100, the substrate 102, the isolation structure 103, the anode 104, the protective layer 106, the OLED material 112, the cathode 114, the encapsulation layer 116, the global encapsulation layer 118, the wells 105, the overhang structures 110, the opening 115, the sub-pixel lines 107A, 107B, 107C, the sub-pixels 108A, 108B, 108C, 108D, 108E, 108F, the busbars 150, and/or method 300 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel circuit, comprising:
at least two isolation structures disposed over a substrate, adjacent isolation structures defining a well;
anodes disposed over an upper surface of the isolation structures;
overhang structures, the overhang structures having a layer with:
an upper portion having a bottom surface disposed on an outer portion of the anodes;
a lower portion with a lowermost surface disposed on the isolation structures and extending past a lower sidewall of the isolation structures and over the well; and
an upper sidewall, adjacent upper sidewalls defining an opening of the well;
an organic light emitting diode (OLED) material;
a cathode; and
an encapsulation layer.

2. The sub-pixel circuit of claim 1, wherein the isolation structures comprise an isolation material and the overhang structures comprise an overhang material.

3. The sub-pixel circuit of claim 2, wherein the isolation material and the overhang material are different.

4. The sub-pixel circuit of claim 2, wherein the isolation material has a first etch rate and the overhang material has a second etch rate when exposed to an etchant.

5. The sub-pixel circuit of claim 4, wherein the first etch rate and the second etch rate are different.

6. The sub-pixel circuit of claim 1, wherein the cathode is disposed over the overhang structures and within the well.

7. The sub-pixel circuit of claim 2, wherein the encapsulation layer extends under at least a portion of the overhang structures along the lower sidewall of the isolation structures, and contacts the lower surface of the overhang structures.

8. The sub-pixel circuit of claim 1, wherein the OLED material is disposed over the substrate within the well.

9. The sub-pixel circuit of claim 1, further comprising a protective layer disposed on the substrate within the well and extending below the isolation structures.

10. The sub-pixel circuit of claim 1, wherein the OLED material disposed within the well contacts the lower sidewall of the isolation structures.

11. The sub-pixel circuit of claim 1, wherein a first thickness of the OLED material disposed over the anodes and the overhang structures is greater than a second thickness of the OLED material disposed within the well.

12. The sub-pixel circuit of claim 2, wherein the isolation material comprises silicon oxide.

13. The sub-pixel circuit of claim 2, wherein the overhang material comprises aluminum oxide.

14. The sub-pixel circuit of claim 2, further comprising:
a global encapsulation layer disposed over the encapsulation layer.

15. The sub-pixel circuit of claim 14, wherein the global encapsulation layer fills the well and the opening between the adjacent upper sidewalls of the overhang structures.

16. A device, comprising:
a first sub-pixel and a second sub-pixel each comprising:
isolation structures comprising an isolation material, the isolation structures disposed over a substrate, the isolation structures further comprising an outer portion and a lower sidewall;
anodes disposed over the isolation structures, the anodes comprising an uppermost surface;
a plurality of overhang structures comprising an overhang material, the overhang structures disposed over the outer portion of the isolation structures, the plurality of overhang structures further comprising:
an upper portion having a bottom surface disposed on an outer portion of the anodes; and
a lower portion with a lowermost surface disposed on of the isolation structures and extending past the lower sidewall of the isolation structures, a portion of the bottom surface extending past the lower sidewall of the isolation structures defining an overhang extension, wherein the lower sidewall of the isolation structure and a bottom surface of the overhang extension of the lower portion partially define a trench area; and
an organic light emitting diode (OLED) material.

17. The device of claim 16, wherein the isolation material has a first etch rate and the overhang material has a second etch rate.

18. The device of claim 17, wherein the first etch rate and the second etch rate are different.

19. The device of claim 16, wherein a cathode is disposed over the overhang structures and within the trench area.

20. The device of claim 16, wherein an encapsulation layer extends under at least a portion of the overhang structures and along the lower sidewall of the isolation structures, and contacts the lower surface of the overhang extension of the overhang structures.

21. A method comprising:
depositing an isolation layer over a substrate;
depositing an anode layer over the isolation layer;
forming a plurality of anodes using a photolithography process;
depositing an overhang layer over the isolation layer and the anodes;
etching a portion of the overhang layer; and
performing a reactive ion etching (RIE) process to form a plurality of isolation structures and a plurality of overhang structures.

22. The method of claim 21 further comprising:
depositing a first OLED material and a first cathode over a first sub-pixel line and a second sub-pixel line;
removing the first OLED material and the first cathode deposited over the second sub-pixel line using a photolithography process;
depositing a second OLED material and a second cathode over a first sub-pixel line and a second sub-pixel line; and
removing the second OLED material and the second cathode deposited over the first sub-pixel line using a photolithography process.

23. The method of claim 21, wherein the RIE process comprises:
patterning a photoresist over the anodes and the overhang layer, wherein the photoresist comprises an opening formed over a portion of the overhang layer;
performing a first etching process, wherein the first etching process widens the opening;
performing a second etching process, wherein the second etching process forms a channel in the overhang layer and the isolation layer; and
performing a third etching process, wherein the third etching process selectively etches the isolation layer within the channel to form a well.

24. The method of claim 23, wherein the first etching process and the second etching process are both an anisotropic process.

25. The method of claim 23, wherein the third etching process is an isentropic process.

26. The method of claim 23, wherein the first etching process comprises an aluminum oxide (Al₂O₃) chlorine (Cl) based dry etchant.

27. The method of claim 23, wherein the second etching process comprises a silicon monoxide (SiO) fluorine (F) based dry etchant.

28. The method of claim 23, wherein the third etching process comprises a silver (Ag) potassium (Kl) based wet etchant, a silver (Ag) iodine (I₂) based wet etchant, or a combination thereof.

29. The method of claim 21, wherein depositing an isolation layer over a substrate further comprises forming a plurality of openings within the isolation layer.

30. The method of claim 21, wherein the method further comprises depositing a protective layer over the substrate.

31. The method of claim 29, further comprising:
depositing a plug-in via metal within the plurality of openings; and
planarizing the plug-in via metal using a chemical mechanical planarization (CMP) process.
